(19) United States
(12) Patent Application Publication
(10) Pub. No.: US 2011/0198112 A1
(43) Pub. Date: Aug. 18, 2011

(54) PRINTED CIRCUIT BOARD AND METHOD FOR MANUFACTURING THE SAME

(75) Inventors: Kwang Soo KIM, Gyunggi-do (KR); Ki Ho SEO, Gyunggi-do (KR)

(73) Assignee: SAMSUNG ELECTRO-MECHANICS CO., LTD., Gyunggi-do (KR)

(21) Appl. No.: 12/874,013

(22) Filed: Sep. 1, 2010

(30) Foreign Application Priority Data
Feb. 12, 2010 (KR) 10-2010-0013580

(51) Int. Cl. H05K 1/09; H01B 13/00

(52) U.S. Cl. 174/257; 216/13

(57) ABSTRACT

Disclosed herein is a method for manufacturing a printed circuit board, including: (A) preparing an aluminum substrate; (B) patterning and etching an etching resist on the aluminum substrate; (C) forming an insulating layer by performing an anodizing treatment on the patterned aluminum substrate; and (D) forming a metal wiring layer by removing the etching resist. The aluminum wiring and the insulating layer are simultaneously formed on the surface of the aluminum patterned by etching through an anodizing method, thereby simplifying the manufacturing process of the substrate and improving adhesion between the metal wiring layer and the insulating layer. In addition, the thickness of the insulating layer and the thickness of the metal wiring layer can be controlled by controlling the anodizing treatment time, thereby providing a method for manufacturing a printed circuit board that can be manufactured to fit for use purpose.

### CROSS REFERENCE TO RELATED APPLICATION

This application claims the benefit of Korean Patent Application No. 10-2010-0013580, filed on Feb. 12, 2010, entitled “Printed Circuit Board And Manufacturing Method of Printed Circuit Board”, which is hereby incorporated by reference in its entirety into this application.

### BACKGROUND OF THE INVENTION

1. Technical Field

The present invention relates to a printed circuit board and a method for manufacturing the same.

2. Description of the Related Art

In general, as a method for forming wirings with a metal such as copper, aluminum, or the like, on a printed circuit board, a subtractive process and an additive process are commonly used. Herein, as a method for manufacturing a printed circuit board by modifying some processes, there are a semi-additive process and a modified semi-additive process, and the like. Even though there have been proposed various methods for manufacturing a printed circuit board as described above, a printed circuit board is completed by finally being subject to an etching step.

Among the method for manufacturing a printed circuit board, a manufacturing method by an additive process will be described by way of example. As shown in FIGS. 1A to 1G, when manufacturing a printed circuit board, at a first step, an aluminum substrate 100 is provided as shown in FIG. 1A, and an anodizing treatment is performed on the aluminum substrate 100 in order to form an insulating layer 110 as shown in FIG. 1B. In FIG. 1C, a seed layer 111 made of a metal material, which is to be a wiring, is stacked on the insulating layer 110. In FIG. 1D, a photo resist layer 112 is stacked on the seed layer 111 and then the photo resist layer 112 is patterned. In FIG. 1E, the patterned structure is plated with a metal layer, thereby forming a patterned metal wiring layer 113. In FIG. 1F, the metal wiring layer 113 is patterned by removing the photo resist layer 112, and in FIG. 1G, after circuit patterns 113 and the seed layer 111 are exposed, the seed layer 111 remaining between the circuit patterns 113 are removed using an etchant.

Herein, since an electroplating is generally used for forming the circuit pattern 113, a seed layer 111 made of a metal material should be formed on the insulating layer 110. However, the seed layer 111 causes all the circuit patterns 113 to short-circuit, such that the seed layer 111 exposed between the circuit patterns 113 should be removed by finally being subject to an etching step.

According to a process for manufacturing an aluminum substrate according to the prior art, an anodized insulating layer 110 is formed after an anodizing process and then a seed layer 111 is formed using a sputtering method that is a dry etching method, or an electroless plating method that is a wet etching method. The seed layer 111 is a buffer layer for forming a circuit on an anodized coating layer and it thus needs good adhesive characteristics with the anodized coating layer. After forming the seed layer 111, a metal wiring 113 is stacked thereon by an electroplating. The adhesion between the seed layer 111 and the insulating coating is weakened due to stress generated during the process. Further, the seed layer 111 used during the electroplating process is still electrically connected even after the metal wiring 113 is formed, causing a complicated problem in the process, such that the seed layer 111 should be etched through an additional etching process. In addition, several problems arise, for example, the loss of a circuit wiring 113, or the like due to over-etching or under-etching at the time of etching the seed layer 111.

### SUMMARY OF THE INVENTION

The present invention has been made in an effort to simultaneously form an aluminum wiring and an insulating layer using an anodizing method on an aluminum surface patterned by etching in a manufacturing process of a printed circuit board, thereby simplifying the manufacturing process of the substrate and improving adhesion between the metal wiring layer and the insulating layer. In addition, the thickness of the insulating layer and the thickness of the metal wiring layer are controlled by controlling an anodizing treatment time, thereby providing a method for manufacturing a printed circuit board that can be manufactured to fit for the purpose of use and the printed circuit board.

A method for manufacturing a printed circuit board according to a preferred embodiment of the present invention includes: (A) preparing an aluminum substrate; (B) patterning and etching the aluminum substrate with an etching resist; (C) forming an insulating layer on the patterned aluminum substrate by performing an anodizing treatment thereon; and (D) forming a metal wiring layer by removing the etching resist.

Herein, the method further includes forming a mask using a photoresist as the etching resist at step (B).

Further, the method further includes forming a mask on the aluminum substrate using a hetero metal layer as the etching resist at step (B).

Further, the hetero metal layer is a nickel (Ni) layer.

Further, the hetero metal layer is a copper (Cu) layer.

Further, step (C) performs the anodizing treatment until anodized layers generated between each patterned aluminum substrate are grown and inter-connected to form an insulating layer.

Further, the insulating layer at step (C) has a V-shaped groove formed at a point where the anodized layers are inter-connected to form the insulating layer.

Further, the method further includes increasing the thickness of the insulating layer formed in proportion to the anodizing treatment time at step (C)

Further, the method further includes controlling the thickness of the metal wiring layer formed according to the anodizing treatment time at step (C).

Further, the metal wiring layer is formed of an aluminum layer.

Further, the metal wiring layer is a nickel (Ni) layer.

Further, the metal wiring layer is a copper (Cu) layer.

A method for manufacturing a double-sided printed circuit board according to another preferred another embodiment of the present invention includes: (A) preparing an aluminum substrate; (B) patterning and etching the top surface and the bottom surface of the aluminum substrate with an etching resist; (C) forming an insulating layer on the top surface and the bottom surface of the patterned aluminum substrate by performing an anodizing treatment thereon; and (D) forming a metal wiring layer on the top surface and the bottom surface of the aluminum substrate by removing the etching resist.

Herein, the method further includes forming a mask on the top surface and the bottom surface of the aluminum substrate using a photoresist as the etching resist at step (B).

Further, the method further includes forming a mask on the top surface and the bottom surface of the aluminum substrate using a hetero metal layer as the etching resist at step (B).

Further, the hetero metal layer is a nickel (Ni) layer.

Further, the hetero metal layer is a copper (Cu) layer.

Further, step (C) performs the anodizing treatment until anodized layers generated between each patterned aluminum substrate are grown and inter-connected to form an insulating layer.

Further, the insulating layer at step (C) has a V-shaped groove formed at a point where the anodized layers are inter-connected upward to the aluminum substrate, and has a [symbol] -shaped groove at a point where the anodized layers are inter-connected downward to the aluminum substrate.

Further, the method further includes increasing the thickness of the insulating layer in proportion to the anodizing time at step (C).

Further, the method further includes controlling the thickness of the metal wiring layer formed on the top surface and the bottom surface of the aluminum substrate according to the anodizing treatment time at step (C).

Further, the metal wiring layer is formed of an aluminum layer.

Further, the metal wiring layer is a nickel (Ni) layer.

Further, the metal wiring layer is a copper (Cu) layer.

A printed circuit board according to the present invention includes: projection parts that are formed on the top surface of an aluminum substrate at a predetermined interval, a groove formed between the projection parts, a “∇”-shaped aluminum metal wiring layer formed downward from the top surface of the projection part, and an insulating layer spaced vertically to the bottom surface of the aluminum substrate and formed below the metal wiring layer.

Herein, the metal wiring layer further includes a nickel (Ni) layer or a copper (Cu) layer on the top of the metal wiring layer

Further, the insulating layer is an anodized layer.

### BRIEF DESCRIPTION OF THE DRAWINGS

FIGS. 1A to 1G are diagrams showing a method for manufacturing a printed circuit board according to the prior art;

FIGS. 2A to 2E are diagrams showing a method for manufacturing a printed circuit board according to an embodiment of the present invention;

FIGS. 3A to 3E are diagrams showing a method for manufacturing a printed circuit board according to another embodiment of the present invention;

FIG. 4 is a diagram showing a shape that an anodized layer is formed when an anodizing treatment is performed to a patterned aluminum substrate;

FIG. 5 is a flowchart showing a method for manufacturing a printed circuit board according to an embodiment of the present invention;

FIGS. 6A to 6D are diagrams showing a method for manufacturing a printed circuit board according to still another embodiment of the present invention; and

FIGS. 7A to 7D are diagrams showing a method for manufacturing a double-sided printed circuit board according to still another embodiment of the present invention.

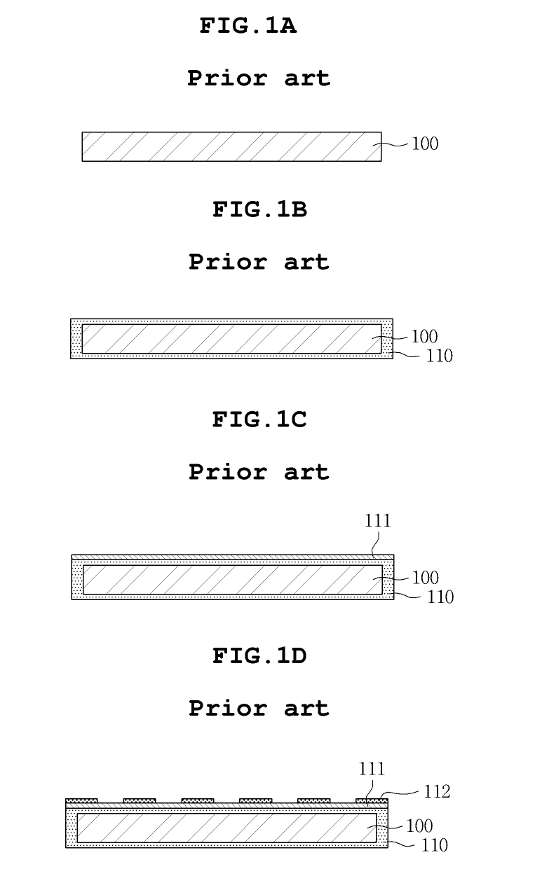

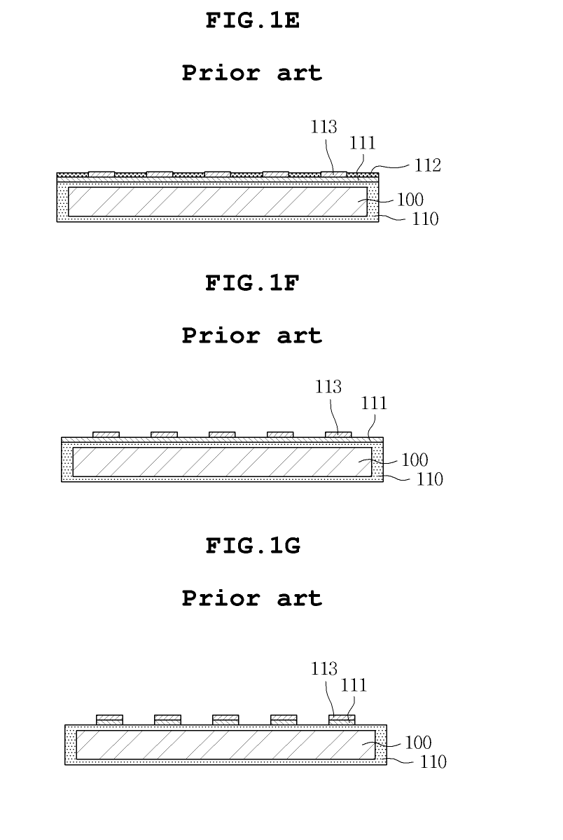

### DESCRIPTION OF THE PREFERRED EMBODIMENTS

Various objects, advantages and features of the invention Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, in describing the present invention, a detailed description of related known functions or configurations will be omitted so as not to obscure the subject of the present invention.

Hereinafter, preferred embodiments of the present invention will be described in detail with reference to the accompanying drawings.

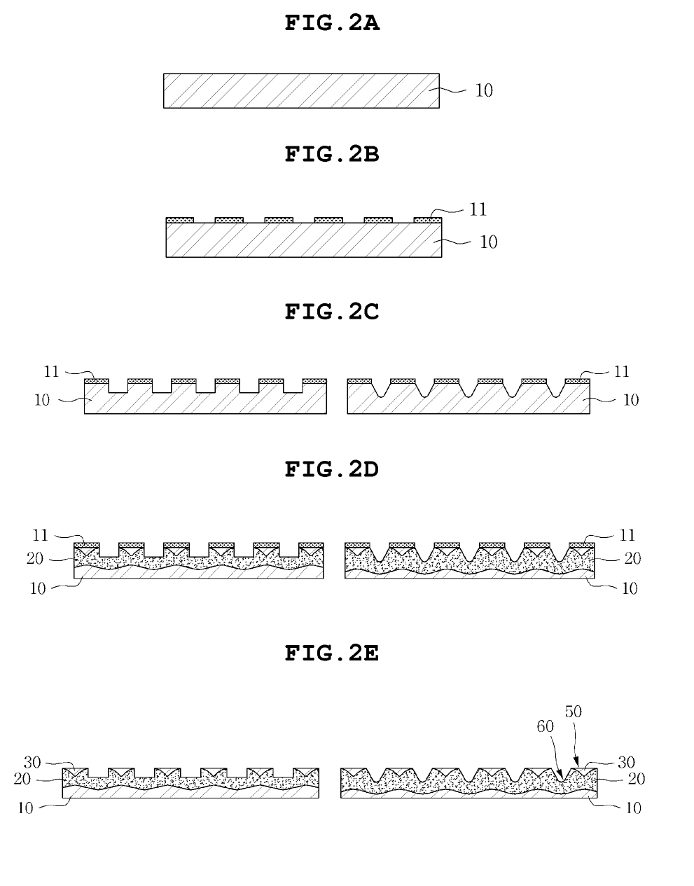

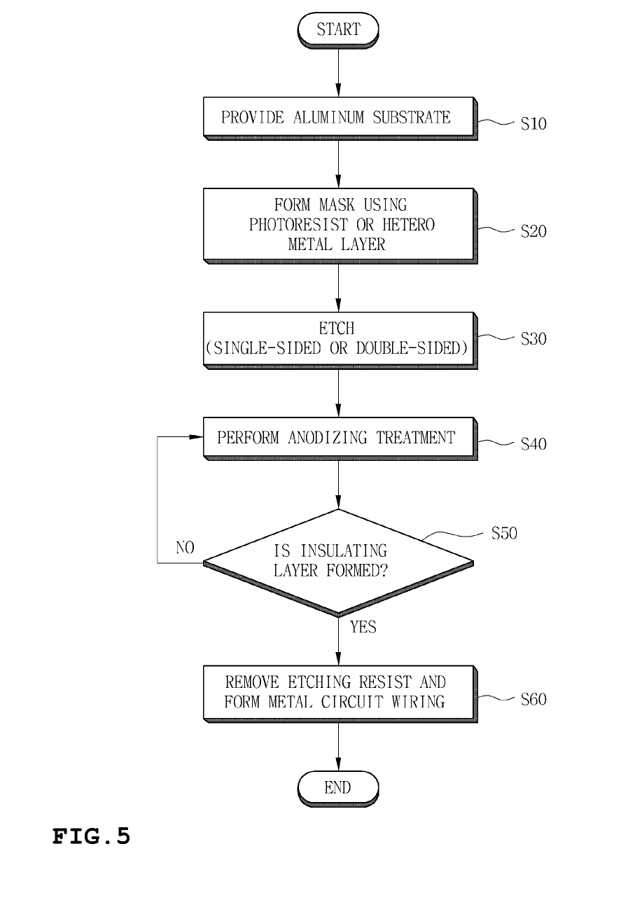

FIGS. 2A to 2E are diagrams showing a method for manufacturing a printed circuit board according to an embodiment of the present invention, FIG. 4 is a diagram showing a shape that an anodized layer is formed when an anodizing treatment is performed to a patterned aluminum substrate 10, and FIG. 5 is a flowchart showing a method for manufacturing a printed circuit board according to an embodiment of the present invention.

The present invention relates to a method for manufacturing a printed circuit board, including: (A) preparing an aluminum substrate 10, (B) patterning and etching the aluminum substrate 10 with an etching resist 11, (C) forming an insulating layer 20 by performing an anodizing treatment on the patterned aluminum substrate 10; and (D) forming a metal wiring layer 30 by removing the etching resist 11.

As shown in FIGS. 2A to 2E, the aluminum substrate 10 is prepared in FIG. 2A. Although there is metal for manufacturing other metal core substrates, it is preferable to use the aluminum substrate 10, in particular, in performing the anodizing treatment.

In FIG. 2B, the etching resist 11 is applied to the aluminum substrate 10. The etching resist 11 is formed for a circuit wiring pattern. The etching resist 11 may use a photoresist. Further, a hetero metal layer 111 may also be used as the etching resist 11. When the hetero metal layer 111 is used as the etching resist 11 of the present invention, it may be preferable to use a metal layer made of metal such as nickel (Ni) or copper (Cu), which are hardly reacted against the anodizing treatment.

In FIG. 2C, the aluminum substrate 10 is etched using the etching resist 11. Through the etching, the aluminum substrate 10 may have a patterned structure to form the circuit wiring. This is different from a method according to the prior art, that is, a plating layer for forming a circuit wiring layer is formed and is then etched. The circuit wiring layer may be formed by a sputtering method that is a dry etching method, or an electroless/electrode plating method that is a wet etching method. The left figure in FIG. 2C shows a case in which the aluminum substrate 10 is patterned by a dry etching method and the right figure in FIG. 2C shows a case in which the aluminum 10 is patterned by a wet etching method.

After the aluminum substrate 10 is patterned, an anodizing treatment starts to be performed onto the patterned aluminum substrate 10 as shown in FIG. 2D. As the anodizing treatment is performed on the aluminum substrate 10, an anodized layer is formed. The anodized layer continuously grows as the anodizing treatment is performed. As the anodizing treatment is performed onto the aluminum substrate 10 having a patterned structure, however, friction force is generated between an interface where anodizing occurs and an interface where the anodizing does not occur. Owing the friction force, a friction interface 40 is formed and the growth of the anodized layer is applied with resistance, such that the growth of the anodized layer is lowered going closer to the friction interface 40, as shown in FIG. 4. Owing to the lowering of the growth of the anodized layer, the insulating layer 20 is formed below the portion covered with the above etching resist 11 as shown in FIG. 2D and at the same time, an aluminum metal layer remains on the top thereof.

Even in this case, in order to form the insulating layer 20 as shown in FIG. 2D, the anodizing time should be controlled so that the patterned metal wiring layer 30 is isolated from the main body of the aluminum substrate 10. When the insulating layer 20 is formed as shown in FIG. 2D by controlling the anodizing time as described above, a printed circuit board formed with the aluminum metal wiring layer 30 is manufactured as shown in FIG. 2E by removing the etching resist 11. In this case, a V-shaped groove is formed on one side of the insulating layer 20 of the aluminum substrate 10 at a point where the insulating layer 20 is formed by inter-connecting the anodized layers due to the anodizing. This is a unique shape formed as the growth of the anodized layer is lowered due to friction force between the interface where the anodizing occurs and the interface where the anodizing does not occur, as shown in FIG. 4.

The anodizing which occurs in the bidirectional patterned portions of the metal wiring layer 30 serves to simultaneously form the metal wiring layer 30 and the insulating layer 20. Further, the anodizing controls the thickness of the insulating layer 20 between the formed metal wiring layer 30 and the main body, thereby serving to control the insulation voltage of the printed circuit board. Further, the anodizing also controls the thickness of the metal wiring layer 30 by controlling the processing time, thereby making it possible to form the metal wiring layer 30 of the printed circuit board according to the purpose of use.

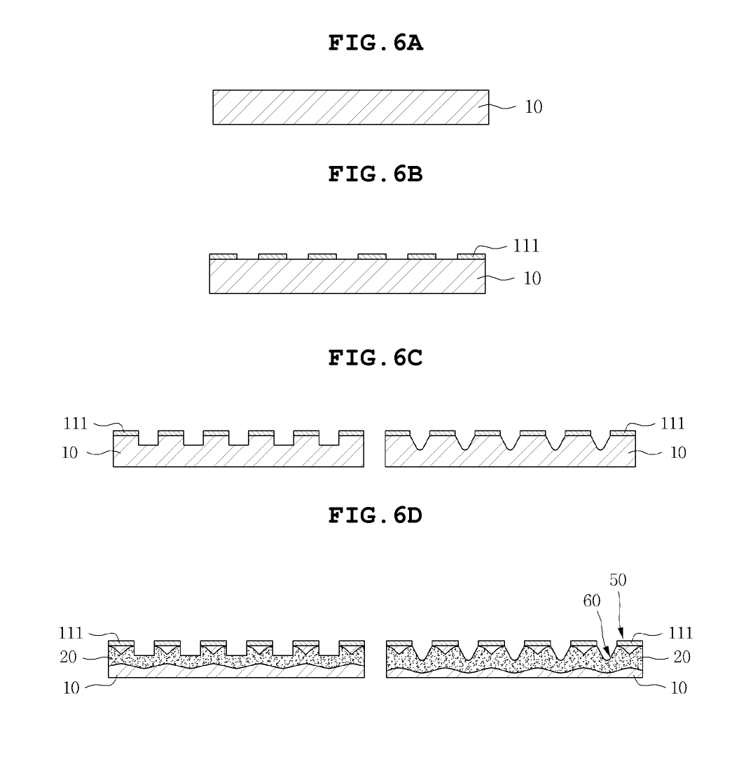

In this connection, FIGS. 6A to 6D are diagrams showing a method for manufacturing a printed circuit board in a case where a hetero metal layer 111 is used as the etching resist 11. Herein, the repetitive description will be omitted. In FIGS. 6A to 6D, since the finally manufactured printed circuit board uses nickel (Ni) or copper (Cu), that is the hetero metal layer 111, as the etching resist 11, nickel (Ni) or copper (Cu) is formed on the top surface of the metal wiring layer 30 of the final printed circuit board, such that the metal wiring layer 30 may be formed together with the aluminum substrate 10.

FIG. 5 describes a method for manufacturing the printed circuit board using a flow chart. This method will be described below.

First, an aluminum substrate is provided in order to manufacture a printed circuit board (S10), wherein a photoresist or the hetero metal layer 111 may be used as an etching resist 11 formed on the aluminum substrate 10. A mask is formed on the aluminum substrate 10 using the photoresist or the hetero metal layer 111 (S20) and an etching is performed (S30). A single-sided etching is performed on a single-sided printed circuit board, but a double-sided etching is performed on a double-sided printed circuit board.

Thereafter, an anodizing treatment is performed onto the aluminum substrate 10 having a patterned structure (S40).

As described above, the anodizing treatment is continuously performed until an anodized layer is formed and grows through the anodizing treatment to form an insulating layer 20 between an aluminum metal wiring layer 30 and the main body of the aluminum substrate 10 (S50). In this case, the thickness of the insulating layer 20 and the thickness of the metal wiring layer 30 can be controlled by controlling the processing time of the anodizing, thereby making it possible to control the insulating voltage of the printed circuit board and form the metal wiring layer 30 fit for use purpose.

When the insulating layer 20 is formed by controlling the processing time of the anodizing as described above, the anodizing treatment is terminated. Thereafter, as the etching resist 11 is removed, the insulating layer 20 and the metal wiring layer 30 can be formed simultaneously through the anodizing treatment (S60). In addition, when the etching resist 11 is replaced by a hetero metal layer 111, finally the metal wiring layer 30 further includes a nickel (Ni) layer or a copper (Cu) layer, that is the hetero metal layer 111, on the top surface thereof.

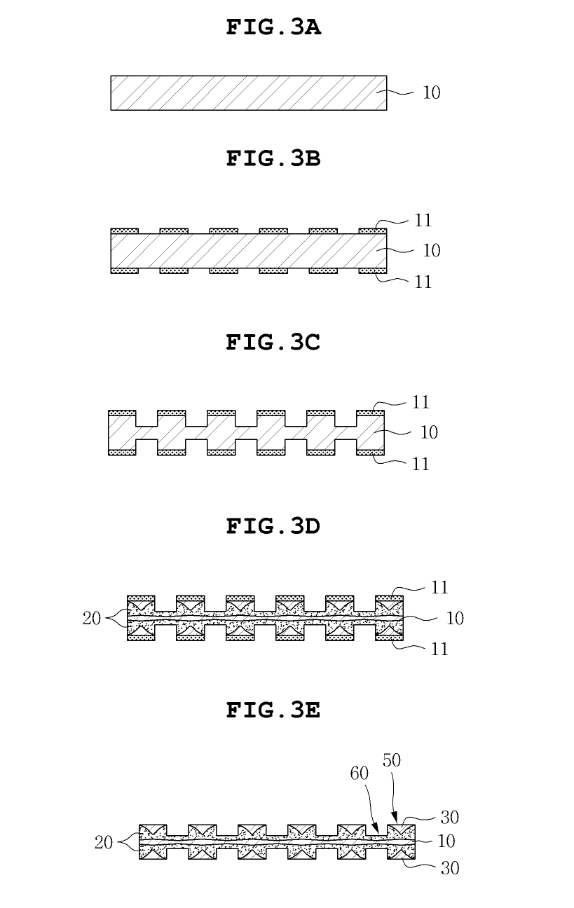

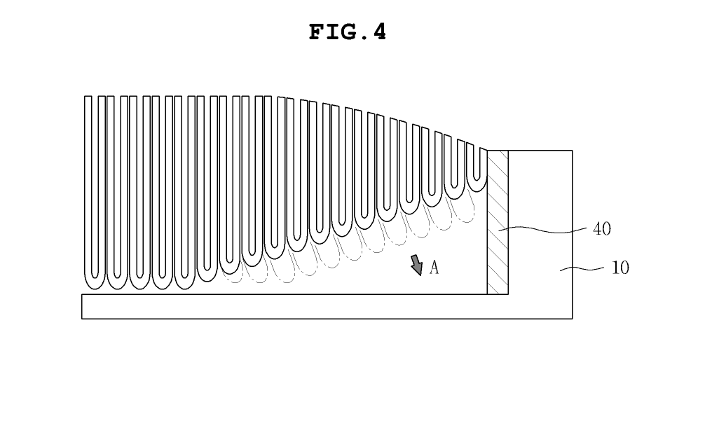

FIGS. 3A to 3E are diagrams showing a method for manufacturing a printed circuit board according to another embodiment of the present invention.

Another embodiment of the present invention relates to a method for manufacturing a double-sided printed circuit board. The overlapping description with the embodiment described above will be omitted.

Another embodiment of the present invention relates to a method for manufacturing a double-sided printed circuit board, including: (A) preparing an aluminum substrate 10, (B) patterning and etching the top surface and the bottom surface of the aluminum substrate 10 with an etching resist 11, (C) forming an insulating layer 20 by performing an anodizing treatment on the top surface and the bottom surface of the patterned aluminum substrate 10; and (D) forming a metal wiring layer 30 on the top surface and the bottom surface of the aluminum substrate 10 by removing the etching resist 11.

In FIG. 3A, an aluminum substrate 10 is provided; in FIG. 3B, the top surface and the bottom surface of the aluminum substrate 10 are patterned using an etching resist 11; in FIG. 3C the patterned aluminum substrate 10 is etched, such that the aluminum substrate 10 has a patterned structure. In FIG. 3D an anodizing treatment is performed, wherein the processing time of the anodizing is controlled so that an insulating layer 20 and a metal wiring layer 30 are formed through the anodizing treatment as described above. When the insulating layer 20 and the metal wiring layer 30 are formed through the anodizing treatment, the double-sided printed circuit board is completed by removing the etching resist 11 as shown in FIG. 3E.

Even in this case, as shown in FIG. 3E, a V-shaped groove is formed on one side of the insulating layer 20 of the top surface of the aluminum substrate 10 at a point where the insulating layer 20 is formed by inter-connecting the anodized layers due to the anodizing and a [symbol] -shaped groove is formed on the other side of the insulating layer 20 of the bottom surface of the aluminum substrate 10. This is a unique shape formed as the growth of the anodized layer is lowered due to friction force between the interface where the anodizing occurs and the interface where the anodizing does not occur, as shown in FIG. 4.

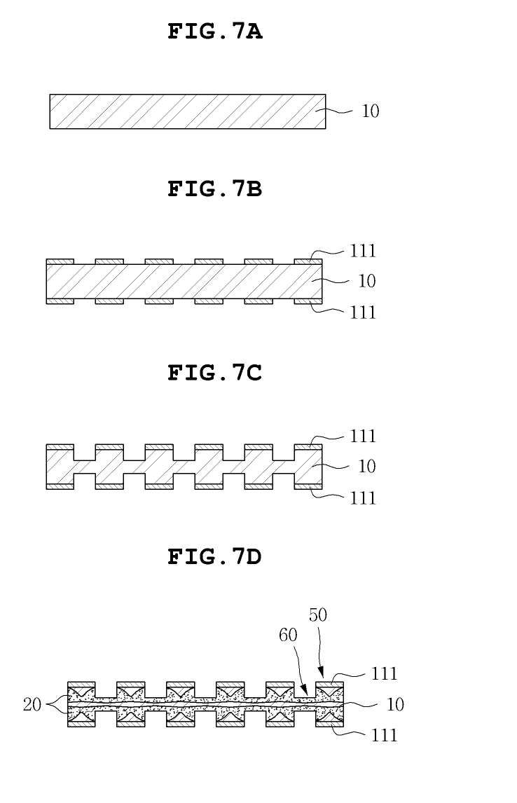

FIGS. 7A to 7D are diagrams showing a method for manufacturing a printed circuit board in a case where a hetero metal layer 111 is used as the etching resist 11. Therefore, the repetitive description will be omitted hereinafter. In FIGS. 7A to 7D, the finally manufactured printed circuit board uses nickel (Ni) or copper (Cu), that is a hetero metal layer 111, instead of the etching resist 11, such that a nickel (Ni) layer or a copper (Cu) layer is further included in the metal wiring layer 30 of the final printed circuit board.

The present invention provides the method for manufacturing a printed circuit board described above and a printed circuit board manufactured therethrough. The printed circuit board is configured to include projection parts 50 that are formed on the top of an aluminum substrate at a predetermined interval, a groove 60 formed between the projection parts, a “∇”-shaped aluminum metal wiring layer 30 formed downward from the top surface of the projection part 50, and an insulating layer 20 spaced vertically to the bottom surface of the aluminum substrate and formed below the metal wiring layer. In connection with the method for manufacturing a printed circuit board, in particular, when the metal wiring layer 30 uses the hetero metal layer 111 instead of the etching resist 11, the metal wiring layer 30 may be formed by further including a copper (Cu) layer or nickel (Ni) layer. In addition, the insulating layer 20 may be formed of an anodized layer. Owing to the forming of the metal wiring layer 30, as described above, fine circuit patterns according to the thickness thereof can be formed and the contact area with the insulating layer 20 below the metal wiring layer 30 can be widen to have a strong adhesion thereof. Further, the insulating layer 20 and the metal wiring layer 30 are continuously formed when manufacturing the printed circuit board, such that the adhesion thereof increases.

According to the present invention, in the method for manufacturing a printed circuit board, the anodizing treatment is performed onto the aluminum substrate patterned by etching to simultaneously form the aluminum metal wiring layer and the insulating layer, thereby making it possible to reduce costs though the simplification of the process and improve adhesion between the insulating layer and the metal wiring layer.

In addition, the thickness of the insulating layer and the thickness of the metal wiring layer generated by controlling the anodizing treatment time of the aluminum substrate are controlled, thereby making it possible to manufacture a printed circuit board fit for the purpose of use.

In addition, it is possible to solve problems which occur according to over-etching or under-etching generated while the seed layer is etched in order to form the known metal wiring layer.

In addition, adhesion between the printed circuit board and the metal wiring layer is improved, thereby making it possible to improve reliability of the printed circuit board.

Although the preferred embodiments of the present invention have been disclosed for illustrative purposes, they are for specifically explaining the present invention and thus a printed circuit board and a method for manufacturing the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A method for manufacturing a printed circuit board, comprising:
(A) preparing an aluminum substrate;
(B) patterning and etching the aluminum substrate with an etching resist;
(C) forming an insulating layer on the etched aluminum substrate by performing an anodizing treatment thereon; and
(D) forming a metal wiring layer by removing the etching resist.

2. The method for manufacturing a printed circuit board as set forth in claim 1, further comprising forming a mask using a photoresist as the etching resist at step (B).

3. The method for manufacturing a printed circuit board as set forth in claim 1, further comprising forming a mask on the aluminum substrate using a hetero metal layer as the etching resist at step (B).

4. The method for manufacturing a printed circuit board as set forth in claim 3, wherein the hetero metal layer is a nickel (Ni) or copper (Cu) layer.

5. The method for manufacturing a printed circuit board as set forth in claim 1, wherein the anodizing treatment at step (C) is continued until it is performed on the patterned portion of the top of the aluminum substrate to grow anodized layers and the anodized layers that are partially anodized to be grown are inter-connected to form an insulating layer.

6. The method for manufacturing a printed circuit board as set forth in claim 5, wherein the insulating layer at step (C) has a V-shaped groove formed at a point where the anodized layers are inter-connected to form the insulating layer.

7. The method for manufacturing a printed circuit board as set forth in claim 5, wherein the thickness of the insulating layer increases in proportion to the anodizing treatment time at step (C).

8. The method for manufacturing a printed circuit board as set forth in claim 5, further comprising controlling the thickness of the metal wiring layer to be formed according to the anodizing treatment time at step (C).

9. The method for manufacturing a printed circuit board as set forth in claim 1, wherein the metal wiring layer is formed of an aluminum layer.

10. The method for manufacturing a printed circuit board as set forth in claim 4, wherein the metal wiring layer further includes a nickel (Ni) or copper (Cu) layer.

11. A method for manufacturing a double-sided printed circuit board, comprising:
(A) preparing an aluminum substrate;
(B) patterning and etching the top surface and the bottom surface of the aluminum substrate with an etching resist;
(C) forming an insulating layer on the top surface and the bottom surface of the patterned aluminum substrate by performing an anodizing treatment thereon; and
(D) forming a metal wiring layer on the top surface and the bottom surface of the aluminum substrate by removing the etching resist.

12. The method for manufacturing a double-sided printed circuit board as set forth in claim 11, further comprising forming a mask on the top surface and the bottom surface of the aluminum substrate using a photoresist as the etching resist at step (B).

13. The method for manufacturing a double-sided printed circuit board as set forth in claim 11, further comprising forming a mask on the top surface and the bottom surface of the aluminum substrate using a hetero metal layer as the etching resist at step (B).

14. The method for manufacturing a double-sided printed circuit board as set forth in claim 13, wherein the hetero metal layer is a nickel (Ni) layer or a copper (Cu) layer.

15. The method for manufacturing a double-sided printed circuit board as set forth in claim 12, wherein the anodizing treatment at step (C) is continued until it is performed onto the patterned portion of the top of the aluminum substrate to grow anodized layers and the anodized layers that are partially anodized to be grown are inter-connected to form an insulating layer.

16. The method for manufacturing a double-sided printed circuit board as set forth in claim 15, wherein the insulating layer at step (C) has a V-shaped groove formed at a point where the anodized layers are inter-connected upward to the aluminum substrate, and has a [symbol] -shaped groove at a point where the anodized layers are inter-connected downward to the aluminum substrate.

17. The method for manufacturing a double-sided printed circuit board as set forth in claim 15, wherein the thickness of the insulating layer increases in proportion to the anodizing treatment time at step (C).

18. The method for manufacturing a double-sided printed circuit board as set forth in claim 15, further comprising changing the thickness of the metal wiring layer formed on the top surface and the bottom surface of the aluminum substrate according to the anodizing treatment time at step (C).

19. The method for manufacturing a double-sided printed circuit board as set forth in claim 11, wherein the metal wiring layer is formed of an aluminum layer.

20. The method for manufacturing a double-sided printed circuit board as set forth in claim 14, wherein the metal wiring layer further includes a nickel (Ni) layer or a copper (Cu) layer.

21. A printed circuit board, comprising:
projection parts formed on the top of an aluminum substrate at a predetermined interval;
a groove formed between the projection parts;
a “∇”-shaped aluminum metal wiring layer formed downward from the top surface of the projection part; and
an insulating layer spaced vertical to the bottom surface of the aluminum substrate and is formed below the metal wiring layer.

22. The printed circuit board as set forth in claim 21, wherein the metal wiring layer further includes a nickel (Ni) layer or a copper (Cu) layer on the top of the metal wiring layer.

23. The printed circuit board as set forth in claim 21, wherein the insulating layer is an anodized layer.
